(19) United States
(12) Patent Application Publication
(10) Pub. No.: US 2025/0234572 A1
(43) Pub. Date: Jul. 17, 2025

(54) SEMICONDUCTOR DEVICE

(71) Applicant: Renesas Electronics Corporation, Tokyo (JP)

(72) Inventor: Yuki IKIRI, Tokyo (JP)

(21) Appl. No.: 18/945,954

(22) Filed: Nov. 13, 2024

(30) Foreign Application Priority Data
Jan. 17, 2024 (JP) 2024-005448

(51) Int. Cl. H01L 29/739; H01L 29/06; H01L 29/423

(52) U.S. Cl. CPC H10D 12/481; H10D 62/127; H10D 64/513

(57) ABSTRACT

A semiconductor device includes, in a gate finger region, a gate potential trench formed on a main surface side of a semiconductor substrate, predetermined potential trenches formed so as to sandwich the gate potential trench on the main surface side of the semiconductor substrate, a drift region of a first conductivity type formed in a first region between the gate potential trench and the predetermined potential trench, and a well region of a second conductivity type, which is a region above the drift region and formed in a second region on a side of the predetermined potential trench opposite to a side where the gate potential trench is located.

### CROSS-REFERENCE TO RELATED APPLICATIONS

The disclosure of Japanese Patent Application No. 2024-005448 filed on Jan. 17, 2024 including the specification, drawings and abstract is incorporated herein by reference in its entirety.

### BACKGROUND

The present invention relates to a semiconductor device.

There are disclosed techniques listed below.
[Patent Document 1] Japanese Unexamined Patent Application Publication No. 2017-79308

For example, Patent Document 1 is known as a technique related to a semiconductor device constituting an insulated gate bipolar transistor (IGBT). Patent Document 1 describes a semiconductor device constituting an EGE (emitter-gate-emitter) type trench gate IGBT. In the semiconductor device of Patent Document 1, a plurality of gate potential trenches having a shape surrounded by a quadrangular outer shape and a quadrangular inner shape in plan view are provided in parallel in a gate wiring lead-out region.

### SUMMARY

In the semiconductor device of Patent Document 1, a plurality of gate potential trenches are formed in a P-type P-well region (floating region), and an N-type drift region is formed in a region inside the inner shape of the gate potential trench in plan view, so that a capacitance formed between a trench gate electrode and the drift region is used as a feedback capacitance Cres. A semiconductor device from which the feedback capacitance Cres can be obtained more effectively is desired.

Other problems and novel features would become apparent from the description of the present specification and the accompanying drawings.

According to an embodiment, a semiconductor device includes a semiconductor substrate including an active cell region where transistors are formed so as to be operable and a gate finger region where a gate wiring is led out. In the gate finger region, a gate potential trench is formed on a main surface side of the semiconductor substrate, and predetermined potential trenches having a predetermined potential different from the gate potential are formed so as to sandwich the gate potential trench on the main surface side of the semiconductor substrate. A drift region of a first conductivity type is formed in a first region between the gate potential trench and the predetermined potential trenches in the semiconductor substrate. A well region of the second conductivity type, which is a region above the drift region of the semiconductor substrate is formed in a second region on a side of the predetermined potential trench opposite to a side where the gate potential trench is located.

According to the embodiment, the feedback capacitance Cres can be obtained more effectively.

### BRIEF DESCRIPTION OF THE DRAWINGS

FIG. 1 is a circuit diagram illustrating a configuration example of a related IGBT parallel connection circuit.

FIG. 2 is a plan view illustrating a schematic configuration of a semiconductor device according to an embodiment.

FIG. 3 is a cross-sectional view illustrating the schematic configuration of the semiconductor device according to the embodiment.

FIG. 4A is a plan view illustrating a configuration example of a semiconductor device according to a first embodiment.

FIG. 4B is a plan view illustrating the configuration example of the semiconductor device according to the first embodiment.

FIG. 5 is a cross-sectional view illustrating a configuration example of a semiconductor device of a comparative example.

FIG. 6 is a cross-sectional view for explaining a parasitic capacitance of the semiconductor device of the comparative example.

FIG. 7 is an enlarged illustrating the configuration example of the semiconductor device according to the first embodiment.

FIG. 8 is an enlarged plan view illustrating the configuration example of the semiconductor device according to the first embodiment.

FIG. 9 is a cross-sectional view illustrating the configuration example of the semiconductor device according to the first embodiment.

FIG. 10 is an enlarged plan view illustrating the configuration example of the semiconductor device according to the first embodiment.

FIG. 11 is a cross-sectional view illustrating the configuration example of the semiconductor device according to the first embodiment.

FIG. 12 is a cross-sectional view for explaining a parasitic capacitance of the semiconductor device according to the first embodiment.

FIG. 13 is a cross-sectional view illustrating the configuration example of the semiconductor device according to the first embodiment.

FIG. 14 is a cross-sectional view illustrating the configuration example of the semiconductor device according to the first embodiment.

FIG. 15 is a cross-sectional view illustrating a configuration example of a semiconductor device according to a second embodiment.

FIG. 16 is a cross-sectional view for explaining a parasitic capacitance of the semiconductor device according to the second embodiment.

FIG. 17 is a cross-sectional view illustrating the configuration example of the semiconductor device according to the second embodiment.

FIG. 18 is a cross-sectional view for explaining the parasitic capacitance of the semiconductor device according to the second embodiment.

FIG. 19 is a cross-sectional view illustrating the configuration example of the semiconductor device according to the second embodiment.

FIG. 20 is a cross-sectional view for explaining the parasitic capacitance of the semiconductor device according to the second embodiment.

### DETAILED DESCRIPTION

Hereinafter, embodiments will be described with reference to the drawings. For clarity of description, the following description and drawings are omitted and simplified as appropriate. In the drawings, the same elements are denoted by the same reference numerals, and redundant description is omitted as necessary.

Each drawing illustrates an XYZ three-dimensional orthogonal coordinate system, and the XY plane is a plane parallel to a surface (front surface or back surface) of a semiconductor substrate. A Z direction orthogonal to the XY plane is a vertical direction, a height direction, or a thickness direction of the semiconductor substrate. The plan view means a view of the XY plane from the Z direction.

### Outline of Embodiment

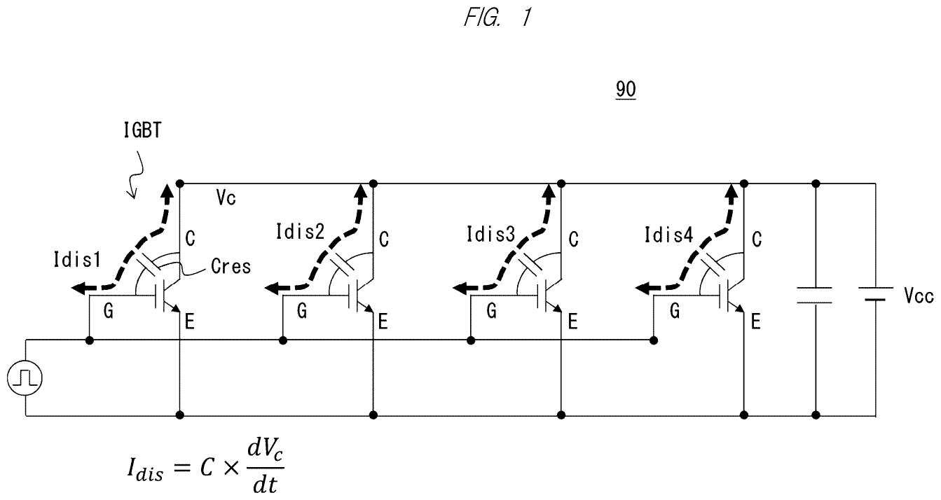

FIG. 1 illustrates a configuration example of a related IGBT parallel connection circuit studied by the inventor. For example, as illustrated in FIG. 1, semiconductor chips constituting an IGBT are connected in parallel and operated to secure a necessary current capacity in an IGBT for a large current inverter. As illustrated in FIG. 1, when a load short circuit test was conducted in a module state in which four IGBTs were connected in parallel, it was observed that oscillation occurred and the semiconductor device was destroyed.

As illustrated in FIG. 1, a displacement current Idis flowed via a feedback capacitance Cres parasitic between the gate and the collector, and the oscillation occurred due to a resonance loop passing via the feedback capacitance Cres. To counter the oscillation, increasing the feedback capacitance Cres (damping capacitance) is effective. For example, in a trench gate type IGBT, it is conceivable to increase the feedback capacitance Cres by adjusting the depth of a gate potential trench connected to a gate potential. However, if the depth of the trench inside an active cell that determines the characteristics of the IGBT is adjusted to increase the feedback capacitance Cres, the basic characteristics of the IGBT may change. In addition, since the depths of all the trenches are uniformly changed due to the manufacturing process, it is difficult to finely adjust the feedback capacitance Cres. Therefore, in the embodiment, a device layout methodology is provided that adds the feedback capacitance Cres in a region that does not affect the characteristics of the IGBT, such as outside the active cell, and allows fine adjustment.

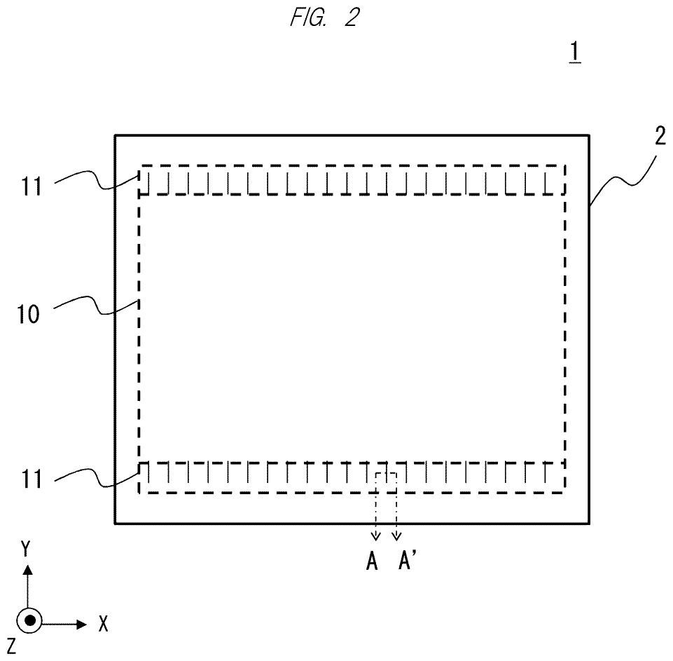

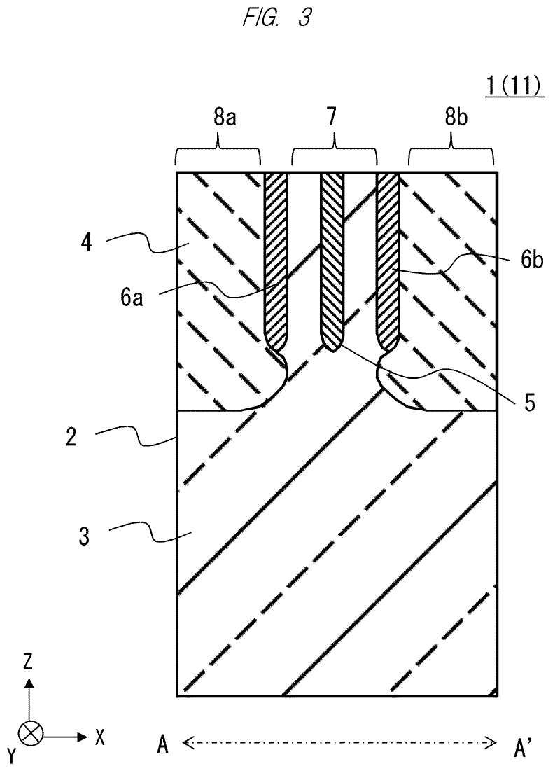

FIG. 2 is a plan view illustrating a schematic configuration of a semiconductor device 1 according to the embodiment. FIG. 3 is a cross-sectional view illustrating a schematic configuration of the semiconductor device 1 in a gate finger region, and illustrates an A-A′ cross section in FIG. 2. The semiconductor device 1 constitutes, for example, a trench gate type IGBT. The semiconductor device 1 may be another semiconductor device having the configurations in FIGS. 2 and 3. For example, the semiconductor device 1 may constitute a transistor such as a power metal-oxide-semiconductor field-effect transistor (MOSFET), other semiconductor elements, or the like.

As illustrated in FIG. 2, the semiconductor device 1 includes a semiconductor substrate 2. The semiconductor substrate 2 has an active cell region 10 and a gate finger region 11. The active cell region 10 is a region where an active cell is formed, for example, a region where a transistor such as an IGBT is formed so as to be operable (active). The gate finger region 11 is a region where a gate wiring is led out from the transistor in the active cell region 10. For example, the gate finger region 11 extends along an end portion of the active cell region 10 outside the active cell region 10. The gate finger region 11 is also a non-active cell region where the active cell is not formed.

As illustrated in FIG. 3, in the gate finger region 11 of the semiconductor device 1, a drift region 3, a well region 4, a gate potential trench 5, and a predetermined potential trench 6 are formed in the semiconductor substrate 2.

The gate potential trench 5 is a trench connected to the gate potential. A trench gate electrode is formed inside the gate potential trench 5. The gate potential trench 5 is formed from a main surface side of the semiconductor substrate 2. For example, the main surface of the semiconductor substrate 2 may be referred to as a front surface, but either surface of the semiconductor substrate 2 may be used as the main surface.

The predetermined potential trench 6 is a trench connected to a predetermined potential different from the gate potential. The predetermined potential trench 6 is a trench inside which an electrode having a predetermined potential is formed. For example, when the semiconductor device 1 forms an IGBT, the predetermined potential trench 6 is an emitter potential trench connected to an emitter potential. The predetermined potential trench 6 is formed on the main surface side of the semiconductor substrate 2 and the predetermined potential trenches 6 are disposed so as to sandwich the gate potential trench 5. For example, the predetermined potential trench 6a and the predetermined potential trench 6b face each other across the gate potential trench 5.

The drift region 3 is a semiconductor region of a first conductivity type (for example, N type) formed in the semiconductor substrate 2. The drift region 3 is formed in a first region 7 between the gate potential trench 5 and the predetermined potential trench 6 in the semiconductor substrate 2. For example, the first region 7 includes regions on both sides of the gate potential trench 5. That is, the first region 7 includes a region between the predetermined potential trench 6a and the gate potential trench 5, and a region between the predetermined potential trench 6b and the gate potential trench 5. The gate potential trench 5 is covered with the drift region 3 from the main surface side of the semiconductor substrate 2 to a bottom of the gate potential trench 5.

The well region 4 is a semiconductor region of a second conductivity type (for example, P type) formed above the drift region 3 in the semiconductor substrate 2. The well region 4 is formed in a second region 8 on a side of the predetermined potential trench 6 opposite to a side where the gate potential trench 5 is located (a side facing the gate potential trench 5). For example, the second region 8 includes regions on both sides of the first region 7. That is, the second region 8 includes a second region 8a on a side of the predetermined potential trench 6a opposite to the side where the gate potential trench 5 is located, and a second region 8b on a side of the predetermined potential trench 6b opposite to the side where the gate potential trench 5 is located. The well region 4 is connected to a predetermined potential (for example, emitter potential) and is separated from the gate potential trench 5.

In a semiconductor device, a gate finger region for connecting the gate electrode of the active cell and the gate wiring occupies a certain area. As described above, in the embodiment, a configuration is provided that allows a feedback capacitance to be added to the gate finger region. In the gate finger region, the drift region of the first conductivity type is formed and the well region of the second conductivity type connected to the predetermined potential is not formed in the region between the gate potential trench and the predetermined potential trench such as the emitter potential. This causes the gate potential trench and the well region to be separated from each other, making it possible to effectively obtain the feedback capacitance Cres. By providing such a structure for the gate finger region, it is possible to add the feedback capacitance Cres while suppressing the influence on the characteristics of the transistor.

### First Embodiment

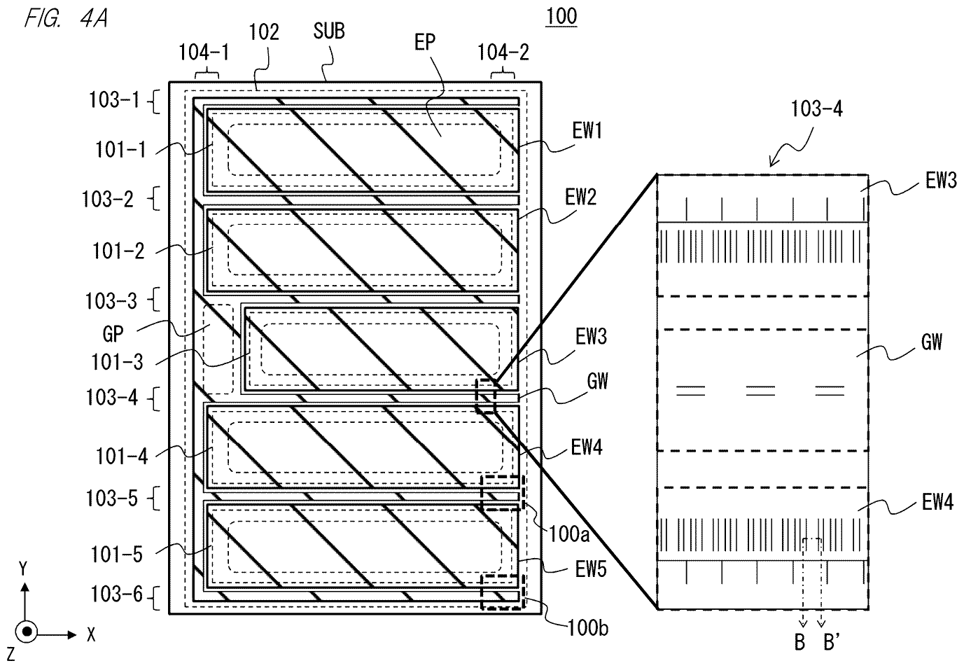

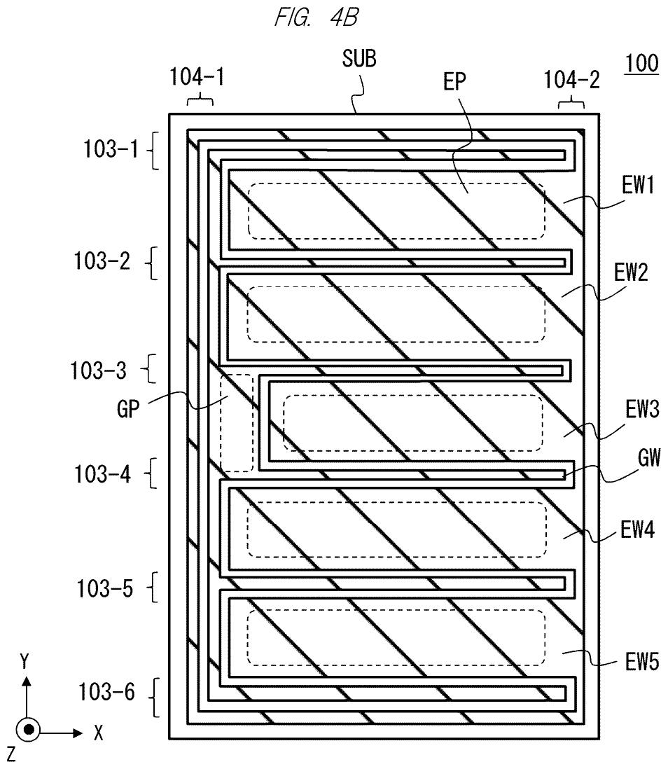

Next, a first embodiment will be described. FIGS. 4A and 4B are plan views illustrating a configuration example of a semiconductor device 100 according to the present embodiment. For example, the semiconductor device 100 constitutes a trench gate type N-channel IGBT. As illustrated in FIG. 1, a plurality of IGBTs are connected in parallel and can be used as a large current inverter. The semiconductor device 100 is not limited to the N-channel IGBT, and may constitute a P-channel IGBT. The semiconductor device 100 is not limited to the trench gate type IGBT, and may constitute a transistor having another structure.

As illustrated in FIG. 4A, the semiconductor device 100 includes a semiconductor substrate SUB that is a semiconductor chip. A gate wiring GW and an emitter wiring EW are formed on the semiconductor substrate SUB. The gate wiring GW is a wiring (electrode) for leading out the gate electrode in the semiconductor substrate SUB. The emitter wiring EW is a wiring (electrode) for leading out the emitter electrode in the semiconductor substrate SUB. For example, the gate wiring GW and the emitter wiring EW are metal films made of aluminum (Al) or the like.

A region overlapping the emitter wiring EW in plan view is an active cell region 101. An outer peripheral end of the active cell region 101 is inside an outer peripheral end of the emitter wiring EW. The active cell region 101 is a region where a main element such as an IGBT is formed so as to be operable in the semiconductor substrate SUB. In this example, emitter wirings EW 1 to EW 5 are disposed in five active cell regions 101-1 to 101-5, respectively. For example, the emitter wiring EW has a rectangular shape in plan view. The five rectangular emitter wirings EW 1 to EW 5 are arrayed in parallel to be equally spaced from each other. For example, the X direction is referred to as a lateral direction (first direction), and the emitter wirings EW 1 to EW 5 extend in the lateral direction.

The gate wirings GW are disposed so as to sandwich the emitter wiring EW (active cell region 101) in a comb shape in plan view. The gate wiring GW may be a linear wire that goes around an outside of the emitter wiring EW. The emitter wiring EW may be formed on the entire inside of the gate wiring GW on the semiconductor substrate SUB. For example, the gate wiring GW is disposed to be separated from the emitter wiring EW in a region between the plurality of emitter wirings EW and a region of an outer peripheral end (excluding the right end) of the semiconductor substrate SUB. It can also be said that the gate wiring GW is disposed in an inactive cell region 102 outside the active cell region 101. The inactive cell region 102 is a region where the main element such as the IGBT is not formed so as to be operable.

For example, a region outside two long sides extending in the lateral direction of the active cell region 101 (emitter wiring EW) in plan view is a gate finger region 103. The gate finger region 103 is a region for leading out the gate wiring from the gate electrode of the active cell and connecting the gate wiring to a gate pad. The gate finger region 103 is included in the inactive cell region 102. The gate finger region 103 extends in the lateral direction along the long side (end portion) of the active cell region 101. The gate wiring GW extending in the lateral direction is disposed in the gate finger region 103.

Both sides of the two long sides of the active cell region 101-1 are gate finger regions 103-1 and 103-2, respectively. The gate finger region 103-1 is a region of a first short-side end portion extending in the lateral direction of the semiconductor substrate SUB. The gate finger region 103-1 includes a gate wiring GW disposed at the first short-side end portion of the semiconductor substrate SUB and a part of the emitter wiring EW 1 facing the gate wiring GW.

Both sides of the two long sides of the active cell region 101-2 are the gate finger region 103-2 and a gate finger region 103-3, respectively. The gate finger region 103-2 is a region between the active cell regions 101-1 and 101-2. The gate finger region 103-2 includes a gate wiring GW between the emitter wirings EW 1 and EW 2, and a part of the emitter wiring EW 1 and a part of the emitter wiring EW 2 facing the gate wiring GW.

Both sides of the two long sides of the active cell region 101-3 are the gate finger region 103-3 and a gate finger region 103-4, respectively. The gate finger region 103-3 is a region between the active cell regions 101-2 and 101-3. The gate finger region 103-3 includes a gate wiring GW between the emitter wirings EW 2 and EW 3, and a part of the emitter wiring EW 2 and a part of the emitter wiring EW 3 facing the gate wiring GW.

Both sides of the two long sides of the active cell region 101-4 are the gate finger region 103-4 and a gate finger region 103-5, respectively. The gate finger region 103-4 is a region between the active cell regions 101-3 and 101-4. The gate finger region 103-4 includes a gate wiring GW between the emitter wirings EW 3 and EW 4, and a part of the emitter wiring EW 3 and a part of the emitter wiring EW 4 facing the gate wiring GW (illustrated in an enlarged view of FIG. 4A).

Both sides of the two long sides of the active cell region 101-5 are the gate finger region 103-5 and a gate finger region 103-6, respectively. The gate finger region 103-5 is a region between the active cell regions 101-4 and 101-5. The gate finger region 103-5 includes a gate wiring GW between the emitter wirings EW 4 and EW 5, and a part of the emitter wiring EW 4 and a part of the emitter wiring EW 5, which face the gate wiring GW. The gate finger region 103-6 is a region of a second short-side end portion extending in the lateral direction of the semiconductor substrate SUB. The gate finger region 103-6 includes a gate wiring GW disposed at the second short-side end portion of the semiconductor substrate SUB and a part of the emitter wiring EW 5 facing the gate wiring GW.

For example, the Y direction is referred to as a longitudinal direction (second direction), and is referred to as an end region 104 of the active cell region 101 extending in the longitudinal direction orthogonal to the lateral direction in which the gate finger region 103 extends. The end region 104 may be included in the inactive cell region 102. An end region 104-1 is a region of a first long-side end portion extending in the longitudinal direction of the semiconductor substrate SUB. For example, a gate wiring GW extending in the longitudinal direction is disposed in the end region 104-1. An end region 104-2 is a region of a second long-side end portion extending in the longitudinal direction of the semiconductor substrate SUB. For example, the gate wiring GW extending in the longitudinal direction is not disposed in the end region 104-2. For example, when the X direction is the left-right direction, the end region 104-1 is a region of the left end portion of the semiconductor substrate SUB. The end region 104-2 is a region of the right end portion of the semiconductor substrate SUB. The gate wiring GW is disposed in the gate finger regions 103-1 to 103-6 and the end region 104-1. It can also be said that the gate wiring GW of the gate finger regions 103-1 to 103-6 and the gate wiring GW of the end region 104-1 are connected to each other. In addition, as illustrated in FIG. 4B, the emitter wiring EW may be formed at the outer peripheral end of the semiconductor substrate SUB so as to surround the gate wiring GW. In this case, the emitter wirings EW1 to EW5 are connected by the emitter wiring EW at the outer peripheral end of the semiconductor substrate SUB.

For example, the surfaces of the gate wiring GW and the emitter wiring EW are covered with a protective film such as a polyimide film. An opening is provided in a part of the protective film, and the gate wiring GW and the emitter wiring EW exposed at the opening are a gate pad GP and an emitter pad EP, respectively. The gate pad GP and the emitter pad EP are external terminals for connecting a bonding wire or the like. For example, the emitter pad EP is formed at the center of each of the emitter wirings EW1 to EW5. The gate pad GP is formed at the center of a left end of the semiconductor substrate SUB, that is, on the left side of the emitter wiring EW 3. In this case, the emitter wiring EW3 at the center has a smaller shape than the other emitter wirings EW.

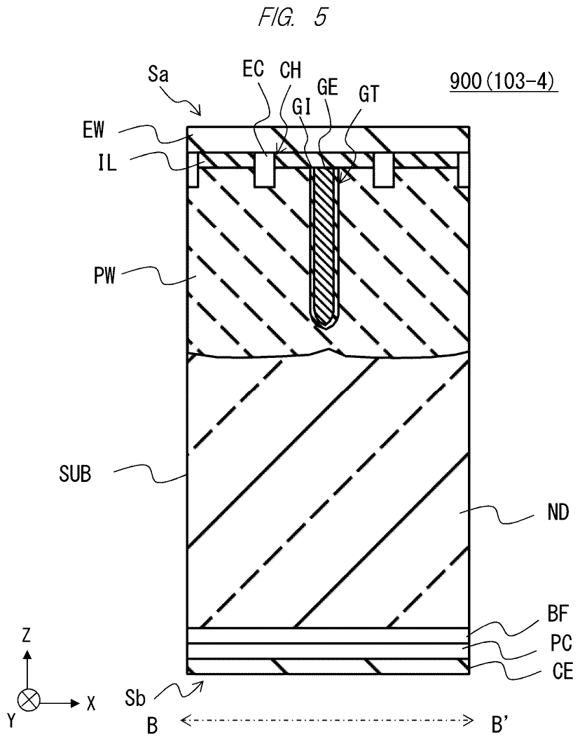

Here, a semiconductor device of a comparative example will be described. FIG. 5 is a cross-sectional view of a gate finger region of a semiconductor device 900 of the comparative example. FIG. 5 illustrates a B-B′ cross-section in the gate finger region 103-4 in FIG. 4A.

For example, the semiconductor substrate SUB is a silicon substrate. An N-drift layer ND (drift region) that is an N-type semiconductor region is formed on a back surface (lower surface) Sb side of the semiconductor substrate SUB. An N buffer layer BF that is an N-type semiconductor region is formed under the N-drift layer ND of the semiconductor substrate SUB. A P collector layer PC that is a P-type semiconductor region is formed under the N buffer layer BF of the semiconductor substrate SUB. A collector electrode CE is formed on the back surface Sb of the semiconductor substrate SUB (under the P collector layer PC). For example, the collector electrode CE is a metal film made of aluminum (Al) or the like.

A P-well region PW that is a P-type semiconductor region is formed on a front surface (upper surface) Sa side of the N-drift layer ND of the semiconductor substrate SUB. The P-well region PW is a region connected to the emitter potential.

A gate potential trench GT for a gate electrode is formed on the front surface Sa side of the semiconductor substrate SUB. A trench gate electrode GE is embedded in the gate potential trench GT via a gate oxide film GI. The trench gate electrode GE is an electrode electrically connected to a gate wiring GW. For example, the trench gate electrode GE is made of N+polysilicon or the like. The gate potential trench GT is formed so as to reach a middle of the P-well region PW from the front surface Sa side of the semiconductor substrate SUB. That is, the P-well region PW is formed up to a position deeper than a bottom (bottom portion) of the gate potential trench GT. The entire region including the bottom of the gate potential trench GT is covered with the P-well region PW. This prevents the electric field intensity from concentrating on the bottom of the gate potential trench GT.

On the front surface Sa side of the semiconductor substrate SUB, an interlayer insulating film IL is formed so as to cover the gate potential trench GT and the P-well region PW. A contact hole CH for an emitter contact EC is formed in the interlayer insulating film IL. The contact hole CH is formed so as to penetrate the interlayer insulating film IL from an upper side (surface side) of the interlayer insulating film IL and reach a region inside the P-well region PW. The emitter contact EC is embedded in an inner surface of the contact hole CH. For example, the emitter contact EC includes a metal plug such as titanium or tungsten.

On the interlayer insulating film IL, the emitter wiring EW such as an aluminum (Al) film is formed so as to cover the interlayer insulating film IL and the emitter contact EC. With this configuration, the emitter wiring EW and the P-well region PW are electrically connected to each other via the emitter contact EC.

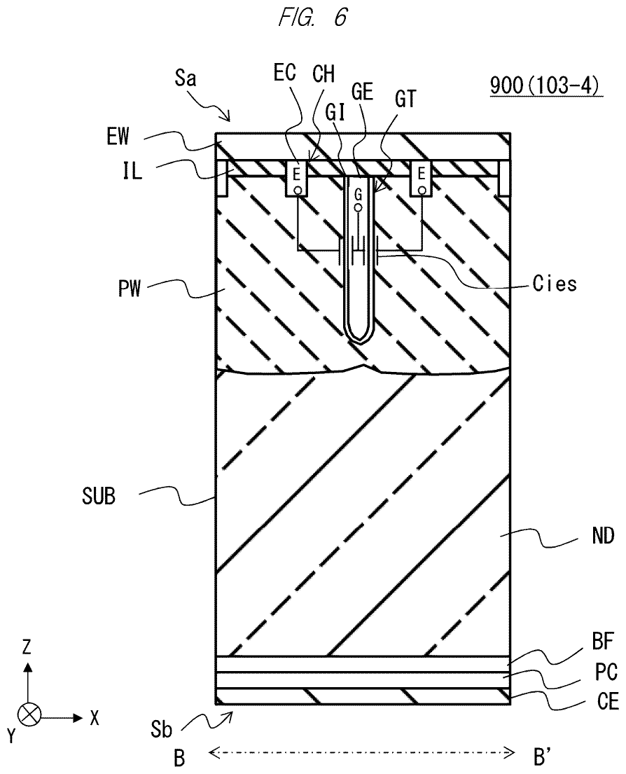

FIG. 6 illustrates a parasitic capacitance generated in the semiconductor device 900 of the comparative example of FIG. 5. As illustrated in FIG. 6, in the semiconductor device 900 of the comparative example, the gate potential trench GT is in contact with the P-well region PW connected to the emitter potential via the gate oxide film GI. With this configuration, an input capacitance Cies parasitic between the gate and the emitter is formed. Therefore, in the structure of the semiconductor device 900 of the comparative example, the feedback capacitance Cres cannot be generated in the gate finger region 103. The present embodiment enables the feedback capacitance Cres to be added by changing the structure of the gate finger region 103.

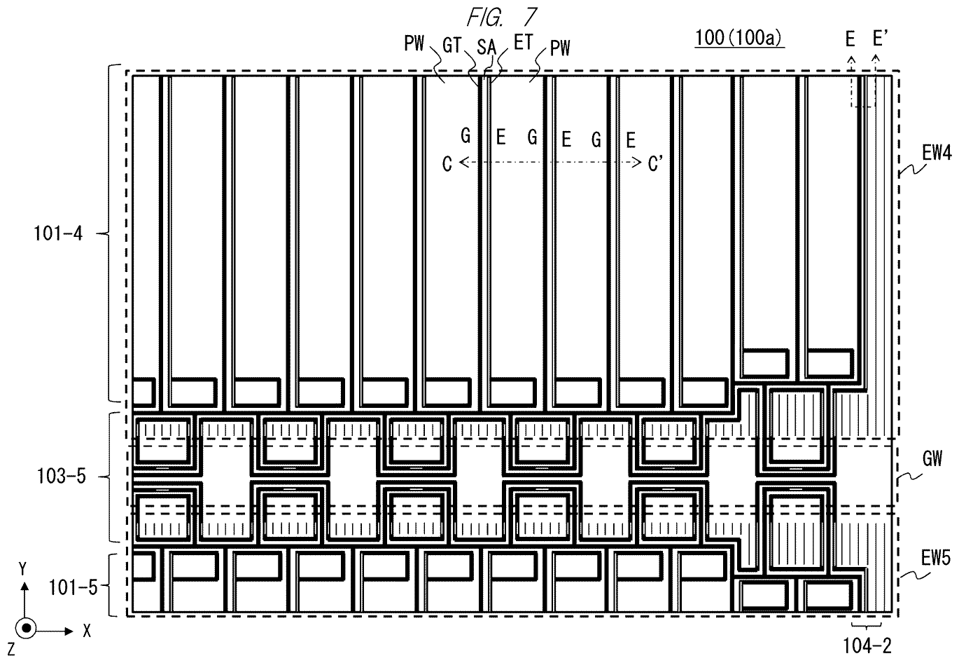

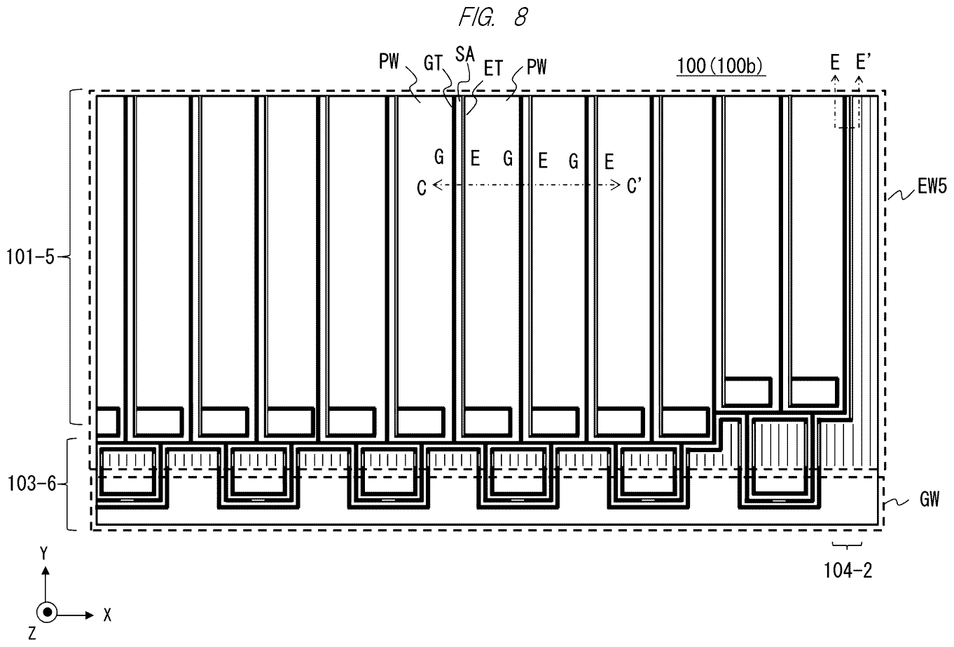

FIGS. 7 and 8 are enlarged plan views of the end portions of the active cell region and the gate finger region of the semiconductor device 100 according to the present embodiment. FIG. 7 is an enlarged plan view of a region 100a including the end portions of the active cell region 101-4, the gate finger region 103-5, and the active cell region 101-5 in FIG. 4A. FIG. 8 is an enlarged plan view of a region 100b including the end portions of the active cell region 101-5 and the gate finger region 103-6 in FIG. 4A. FIGS. 7 and 8 illustrate a state in which the gate wiring, the emitter wiring, and the interlayer insulating film are seen through.

In this example, a gate-emitter (GE) type trench gate IGBT in which a gate potential trench and an emitter potential trench are disposed in one direction to be separated from each other is formed in the active cell region 101. The present embodiment is not limited thereto, and an EGE-type trench gate IGBT in which emitter potential trenches are disposed in one direction to be separated from each other on both sides of a gate potential trench may be formed.

As illustrated in FIGS. 7 and 8, in the active cell region 101 (101-4 in FIGS. 7 and 101-5 in FIG. 8), the gate potential trench GT and the emitter potential trench ET extend linearly in the longitudinal direction to be separated from each other. An N+source region SA is disposed between the gate potential trench GT and the emitter potential trench ET. The gate potential trench GT and the emitter potential trench ET are disposed so as to face each other across the N+source region SA, which constitutes the GE-type trench gate IGBT. The P-well region PW is disposed between a pair of the gate potential trench GT and the emitter potential trench ET and another pair of the gate potential trench GT and the emitter potential trench ET, which constitute the IGBT.

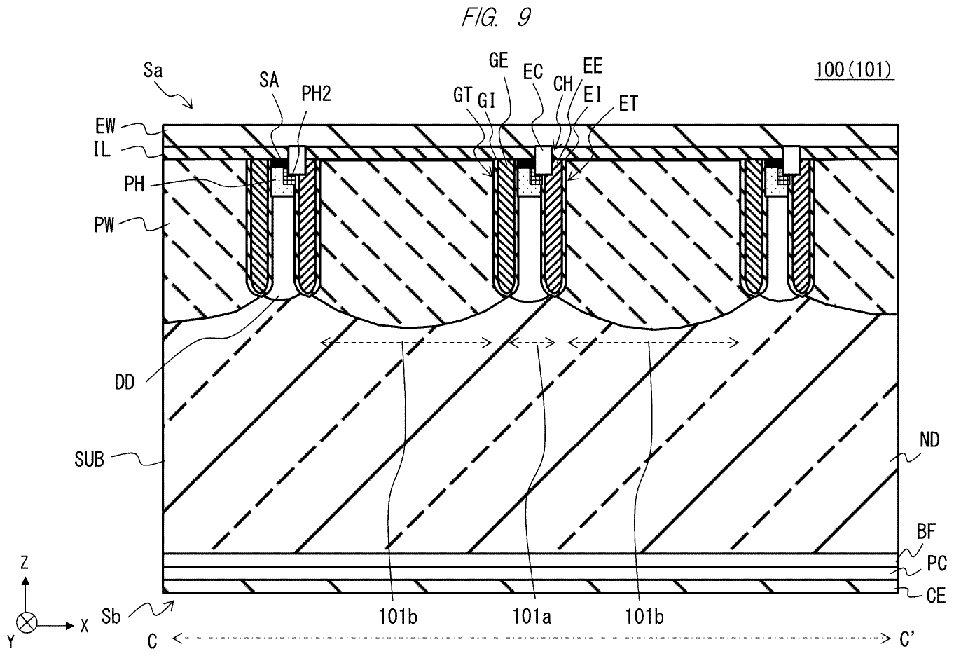

FIG. 9 illustrates a C-C′ cross section of the semiconductor device 100 in FIGS. 7 and 8 in the active cell region 101 (101-4 in FIGS. 7 and 101-5 in FIG. 8). In the example of FIG. 9, the base configuration is the same as that in FIG. 5.

As illustrated in FIG. 9, in the active cell region 101 of the semiconductor device 100, the N-drift layer ND is formed on the semiconductor substrate SUB as in FIG. 5. Furthermore, the N buffer layer BF, the P collector layer PC, and the collector electrode CE are stacked in this order on the back surface Sb side of the N-drift layer ND.

The gate potential trench GT for the gate electrode and the emitter potential trench ET for the emitter electrode are formed on the front surface Sa side of the semiconductor substrate SUB. As in FIG. 5, the trench gate electrode GE is embedded inside the trench of the gate potential trench GT via the gate oxide film GI.

As in the gate potential trench GT, the trench emitter electrode EE is embedded inside the trench of the emitter potential trench ET via the emitter oxide film EI. The trench emitter electrode EE is an electrode electrically connected to the emitter wiring EW. For example, similarly to the trench gate electrode GE, the trench emitter electrode is made of N+polysilicon or the like.

The gate potential trench GT and the emitter potential trench ET are formed so as to reach a middle of the semiconductor substrate SUB from the front surface Sa side of the semiconductor substrate SUB. For example, the gate potential trench GT and the emitter potential trench ET have the same width and the same depth. For example, the width of the trench is a width of an opening of the trench in the lateral direction. The depth of the trench is a length from the surface of the semiconductor substrate SUB to the bottom of the trench.

In a region 101a of the semiconductor substrate SUB between the gate potential trench GT and the emitter potential trench ET, an N-hole barrier layer DD that is an N-type semiconductor region is formed on the N-drift layer ND. In the region 101a, the N-hole barrier layer DD is formed up to the depth of the bottoms of the gate potential trench GT and the emitter potential trench ET. For example, the N-hole barrier layer DD is formed to be deepened from the bottoms of the gate potential trench GT and the bottom of the emitter potential trench ET at the center of the region 101a. The N-type impurity concentration of the N-hole barrier layer DD is higher than the N-type impurity concentration of the N-drift layer ND and lower than the N-type impurity concentration of the N+-type N+source region SA.

In the region 101a, a P-channel layer PH that is a P-type semiconductor region is formed on the N-hole barrier layer DD. In the P-channel layer PH, a P+contact layer PH2 that is a P+-type semiconductor region is formed in a region on the front surface Sa side of the P-channel layer PH and in contact with the emitter potential trench ET. In the region 101a, the N+source region SA (emitter region) that is an N+-type semiconductor region is formed on the P-channel layer PH and the P+contact layer PH2.

In a region 101b of the semiconductor substrate SUB on both sides of the region 101a where the gate potential trench GT and the emitter potential trench ET face each other, the P-well region PW connected to the emitter potential is formed on the N-drift layer ND up to the front surface Sa side of the semiconductor substrate SUB. The region 101b includes a region on a side of the gate potential trench GT opposite to a side where the emitter potential trench ET is located and a region on a side of the emitter potential trench ET opposite to a side where the gate potential trench GT is located. In the region 101b, the P-well region PW is formed up to the depth of the bottoms of the gate potential trench GT and the emitter potential trench ET. For example, the P-well region PW is formed to be deepened from the bottoms of the gate potential trench GT and the bottom of the emitter potential trench ET at the center of the region 101b.

On the front surface Sa side of the semiconductor substrate SUB, the interlayer insulating film IL is formed so as to cover the gate potential trench GT, the emitter potential trench ET, the N+source region SA, and the P-well region PW. In the interlayer insulating film IL, the contact hole CH for the emitter contact EC is formed in a region overlapping a position where the N+source region SA and the emitter potential trench ET are in contact with each other in plan view. The contact hole CH is formed so as to penetrate the interlayer insulating film IL from the upper side (surface side) of the interlayer insulating film IL and reach the N+source region SA, the P-channel layer PH, the P+contact layer PH2, and the trench emitter electrode EE. The emitter contact EC is embedded in an inner surface of the contact hole CH.

Furthermore, on the interlayer insulating film IL, the emitter wiring EW is formed so as to cover the interlayer insulating film IL and the emitter contact EC. Thus, the emitter wiring EW is electrically connected to the N+source region SA, the channel layer PH, the P+contact layer PH2, and the trench emitter electrode EE via the emitter contact EC.

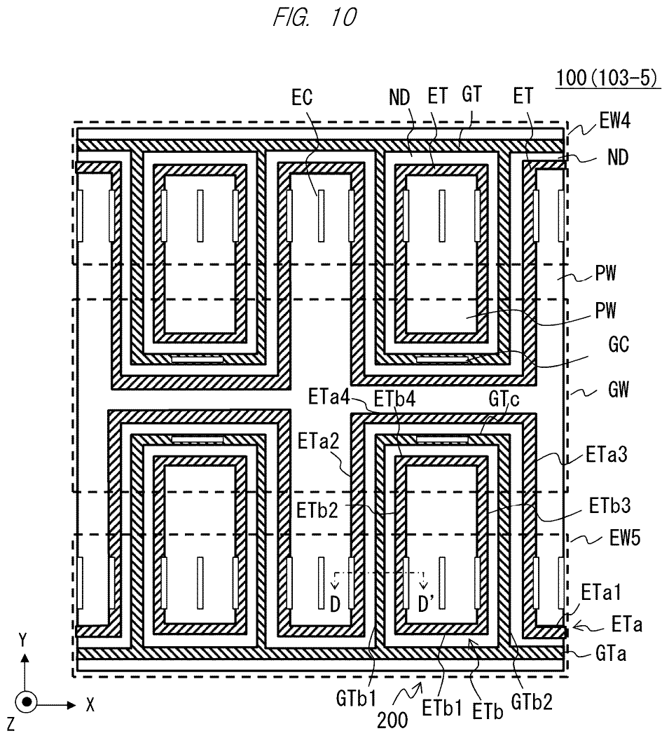

FIG. 10 is an enlarged plan view of the gate finger region of the semiconductor device 100 according to the present embodiment. FIG. 10 is a further enlarged plan view of the gate finger region 103-5 in the region 100a in FIG. 7. Note that in the case of the gate finger region 103-6 in the region 100b in FIG. 8, the configuration is half of that in FIG. 10 (upper half of the drawing).

As illustrated in FIG. 10, in the gate finger region 103 (for example, 103-5), the gate potential trenches GT are disposed to extend in a comb shape (finger shape) in plan view. In the example of FIG. 10, two comb-shaped gate potential trenches GT are disposed to face each other. A comb-shaped portion 200 and another comb-shaped portion 200 face each other. The gate potential trench GT includes an extending portion GTa extending linearly in the lateral direction and a protruding portion GTb protruding linearly in the longitudinal direction orthogonal to the extending portion GTa.

A protruding portion GTb1 and a protruding portion GTb2 extending from the extending portion GTa are connected to each other by a connecting portion GTc in the lateral direction at end portions to which the protruding portion GTb1 and the protruding portion GTb2 extend. The extending portion GTa, the protruding portion GTb1, the protruding portion GTb2, and the connecting portion GTc constitute the comb-shaped portion 200 having a quadrangular shape in plan view.

A gate contact GC is formed on the gate potential trench GT overlapping the gate wiring GW in plan view. For example, the gate contact GC extending in the lateral direction is formed at the center on the connecting portion GTc extending in the lateral direction. The gate contact GC may be formed in other regions as long as the gate wiring GW and the gate potential trench GT overlap each other in plan view.

The gate contact GC has the same structure as that of the emitter contact EC. That is, a contact hole penetrating the interlayer insulating film IL from the upper side (surface side) of the interlayer insulating film IL to reach the trench gate electrode GE is formed, and the gate contact GC is embedded in the contact hole. The gate wiring GW and the trench gate electrode GE are electrically connected to each other via the gate contact GC.

As illustrated in FIG. 10, in the gate finger region 103, the emitter potential trenches ET are disposed along both sides of the comb-shaped gate potential trench GT. That is, the emitter potential trenches ET are disposed so as to sandwich the comb-shaped gate potential trench GT. The emitter potential trenches ET extend linearly along the same direction as the gate potential trench GT at positions on both sides of the gate potential trench GT and separated from the gate potential trench GT.

The emitter potential trench ET includes an outer portion ETa disposed outside the comb-shaped portion 200 of the gate potential trench GT in plan view, and an inner portion ETb disposed inside the comb-shaped portion 200 of the gate potential trench GT in plan view.

The outer portion ETa extends in a comb shape along the gate potential trench GT at a position outside the comb-shaped portion 200 of the gate potential trench GT. The outer portion ETa includes an outer portion ETa1 facing the extending portion GTa of the gate potential trench GT and extending in the lateral direction, an outer portion ETa2 facing the protruding portion GTb1 of the gate potential trench GT and extending in the longitudinal direction, an outer portion ETa3 facing the protruding portion GTb2 of the gate potential trench GT and extending in the longitudinal direction, and an outer portion ETa4 facing the connecting portion GTc of the gate potential trench GT and extending in the lateral direction.

The inner portion ETb is disposed in a quadrangular shape in plan view along the gate potential trench GT at a position inside the comb-shaped portion 200 of the gate potential trench GT. The inner portion ETb includes an inner portion ETb1 facing the extending portion GTa of the gate potential trench GT and extending in the lateral direction, an inner portion ETb2 facing the protruding portion GTb1 of the gate potential trench GT and extending in the longitudinal direction, an inner portion ETb3 facing the protruding portion GTb2 of the gate potential trench GT and extending in the longitudinal direction, and an inner portion ETb4 facing the connecting portion GTc of the gate potential trench GT and extending in the lateral direction.

The outer portion ETa2 and the inner portion ETb2 of the emitter potential trenches face each other so as to sandwich the protruding portion GTb1 of the gate potential trench. The outer portion ETa3 and the inner portion ETb3 of the emitter potential trenches face each other so as to sandwich the protruding portion GTb2 of the gate potential trench. The outer portion ETa4 and the inner portion ETb4 of the emitter potential trenches face each other so as to sandwich the connecting portion GTc of the gate potential trench.

The N-drift layer ND is disposed in regions where the gate potential trench GT is sandwiched by the emitter potential trenches ET. That is, the N-drift layer ND is disposed in a region between the outer portion ETa of the emitter potential trench and the gate potential trench GT and in a region between the inner portion ETb of the emitter potential trench and the gate potential trench GT.

The P-well region PW is disposed in a region on the side of the emitter potential trench ET opposite to the side where the gate potential trench GT is located. That is, the P-well region PW is disposed inside a region surrounded by the inner portion ETb of the emitter potential trench. As illustrated in FIG. 10, when the outer portions ETa of the emitter potential trenches ET face each other in the longitudinal direction, the P-well region PW is disposed in a region between the outer portions ETa of the facing emitter potential trenches ET. Note that, when the outer portion ETa of the emitter potential trench ET faces the end portion of the semiconductor substrate SUB, the P-well region PW is disposed in a region between the outer portion ETa of the emitter potential trench ET and the end portion of the semiconductor substrate SUB.

The emitter contact EC is formed on the emitter potential trench ET and the P-well region PW overlapping the emitter wiring EW in plan view. For example, a plurality of emitter contacts EC extending in the longitudinal direction are disposed in parallel in the lateral direction. The emitter contact EC is formed at a position where the inner portion ETb2 of the emitter potential trench is in contact with the P-well region, a position at the center of the P-well region between the inner portion ETb2 and the inner portion ETb3 of the emitter potential trench, and a position where the inner portion ETb3 of the emitter potential trench is in contact with the P-well region. Thus, the emitter wiring EW is electrically connected to the trench emitter electrode EE and the P-well region PW via the emitter contact EC.

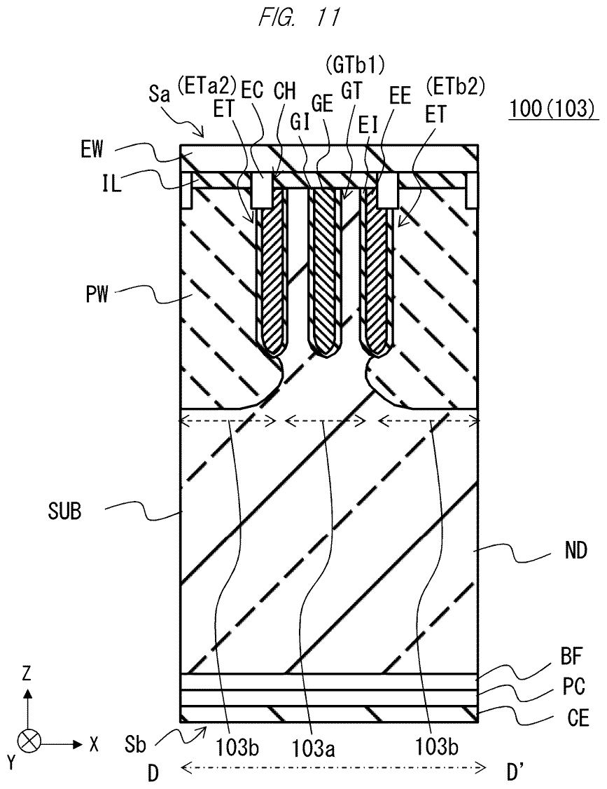

FIG. 11 illustrates an example of a D-D′ cross section of the semiconductor device 100 in FIG. 10 in the gate finger region 103 (for example, 103-5). In the example of FIG. 11, the base configuration is the same as that in FIGS. 5 and 9.

As illustrated in FIG. 11, in the gate finger region 103 of the semiconductor device 100, the N-drift layer ND is formed on the semiconductor substrate SUB as in FIGS. 5 and 9. Furthermore, the buffer layer BF, the P collector layer PC, and the collector electrode CE are stacked in this order on the back surface Sb side of the N-drift layer ND.

The gate potential trench GT and the emitter potential trench ET are formed on the front surface Sa side of the semiconductor substrate SUB. As in FIGS. 5 and 9, the trench gate electrode GE is embedded inside the trench of the gate potential trench GT via the gate oxide film GI. As in FIG. 9, the trench emitter electrode EE is embedded inside the trench of the emitter potential trench ET via the emitter oxide film EI.

As in FIG. 9, the gate potential trench GT and the emitter potential trench ET are formed so as to reach a middle of the semiconductor substrate SUB from the front surface Sa side of the semiconductor substrate SUB. In the example of FIG. 11, the gate potential trench GT and the emitter potential trench ET of the active cell region 101 have the same width and the same depth as those in FIG. 9.

As described with reference to FIG. 10, in the gate finger region 103, the emitter potential trenches ET are formed so as to sandwich the gate potential trench GT. For example, the gate potential trench GT (for example, the protruding portion GTb1 in FIG. 10) is sandwiched between the first emitter potential trench ET (for example, the outer portion ETa2 in FIG. 10) and the second emitter potential trench ET (for example, the inner portion ETb2 in FIG. 10).

In a region 103a (first region) where the emitter potential trenches ET sandwich the gate potential trench GT, the N-drift layer ND is formed up to the front surface Sa side of the semiconductor substrate SUB. The region 103a includes a region (facing region) between the first emitter potential trench ET (for example, the outer portion ETa2 in FIG. 10) and the gate potential trench GT, and a region (facing region) between the second emitter potential trench ET (for example, the inner portion ETb2 in FIG. 10) and the gate potential trench GT. The gate potential trench GT is covered with the N-drift layer ND from the front surface Sa side of the semiconductor substrate SUB to the bottom of the trench. In the region 103a, the P-well region PW as illustrated in FIG. 5 is not formed. In addition, in the region 103a, since the N+source region SA as illustrated in FIG. 9 is not formed, the region does not operate as a transistor.

In the region 103b (second region) on both sides of the region 103a where the emitter potential trenches ET sandwich the gate potential trench GT, the P-well region PW is formed on the N-drift layer ND up to the front surface Sa side of the semiconductor substrate SUB. The region 103b includes the region on a side of the first emitter potential trench ET (for example, the outer portion ETa2 in FIG. 10) opposite to the side where the gate potential trench GT is located and the region on the side of the emitter potential trench ET (for example, the inner portion ETb2 in FIG. 10) opposite to the side where the gate potential trench GT is located. In the region 103b, the P-well region PW is formed on the N-drift layer ND, as in FIGS. 5 and 9.

For example, the P-well region PW is formed from the front surface Sa side of the semiconductor substrate SUB to a position deeper than the bottoms of the gate potential trench GT and the emitter potential trench ET in the region 103b. For example, the P-well region PW protrudes from the regions 103b toward the region 103a at the bottom position of the two emitter potential trenches ET, but is separated by the emitter potential trench ET. The P-well region on both sides of the region 103a tries to spread to the region 103a side when being formed, but is pressed by the emitter potential trench ET and thus kept separated. As a result, the P-well region PW and the gate potential trench GT are separated from each other.

On the front surface Sa side of the semiconductor substrate SUB, the interlayer insulating film IL is formed so as to cover the gate potential trench GT, the emitter potential trench ET, the N-drift layer ND, and the P-well region PW. In the interlayer insulating film IL, the contact hole CH for the emitter contact EC is formed in a region overlapping a position where the P-well region PW and the emitter potential trench ET are in contact with each other in plan view. The contact hole CH is formed so as to penetrate the interlayer insulating film IL from the upper side (surface side) of the interlayer insulating film IL and reach the trench emitter electrode EE and the P-well region PW. The emitter contact EC is embedded in an inner surface of the contact hole CH.

Furthermore, on the interlayer insulating film IL, the emitter wiring EW is formed so as to cover the interlayer insulating film IL and the emitter contact EC. Thus, the emitter wiring EW is electrically connected to the trench emitter electrode EE and the P-well region PW via the emitter contact EC.

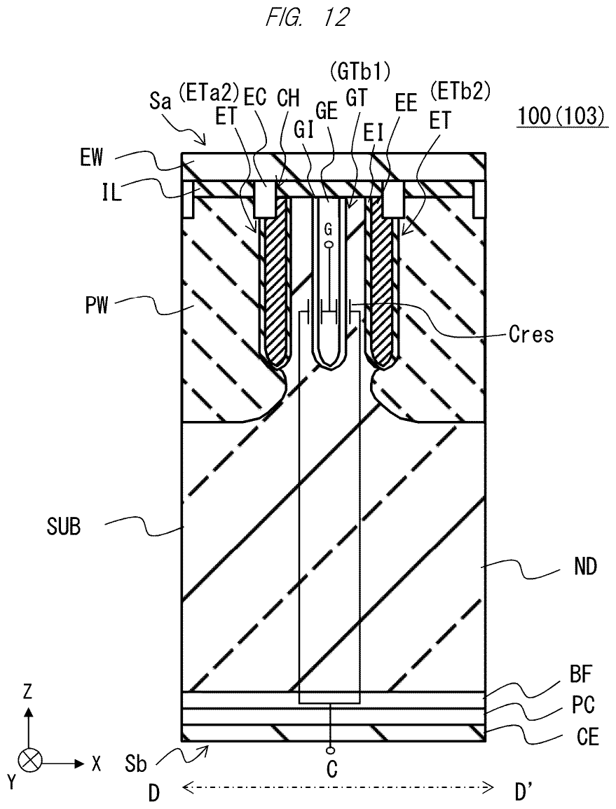

FIG. 12 illustrates a parasitic capacitance generated in the semiconductor device 100 in FIG. 11. As illustrated in FIG. 12, in the semiconductor device 100 according to the present embodiment, the gate potential trench GT is not in contact with the P-well region PW unlike the comparative example of FIG. 6. With this configuration, the input capacitance Cres parasitic between the gate and the collector is formed. Specifically, the feedback capacitance Cres is formed between the entire surface of the gate potential trench GT and the N-drift layer ND. For example, the feedback capacitance Cres depends on an area where the gate potential trench GT and the N-drift layer ND are in contact with each other.

Unlike the comparative example of FIG. 6, the structure in FIG. 12 does not have the P-well region PW for relaxing the electric field at the bottom portion of the gate potential trench GT, and thus the electric field intensity may concentrate at the bottom portion. However, the structure illustrated in FIG. 12 in which the emitter potential trench ET is disposed on both sides of the gate potential trench GT is equivalent to that of the EGE-type trench gate IGBT, and thus there is no problem with the withstand voltage. In addition, the electric field intensity applied to the gate potential trench GT can be dispersed to the emitter potential trench ET by narrowing a pitch between the gate potential trench GT and the emitter potential trench ET, and thus the withstand voltage is unlikely to drop due to electric field concentration.

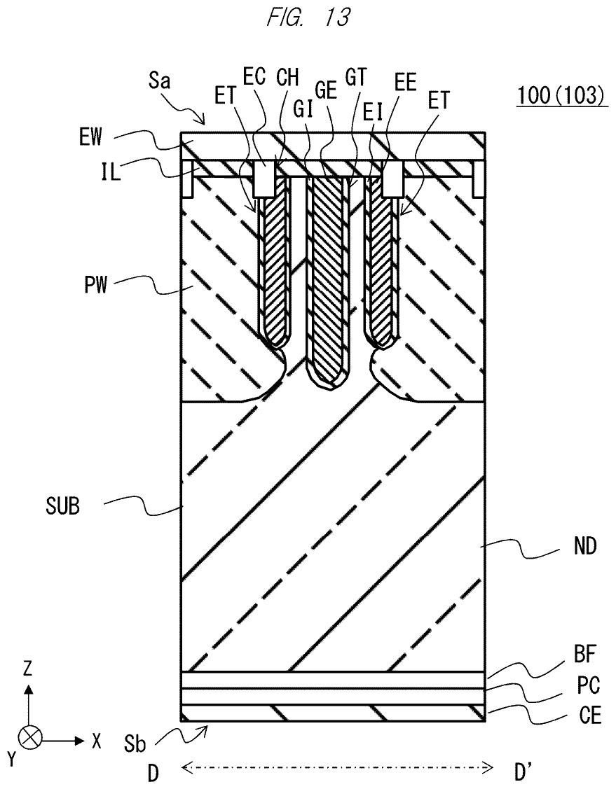

FIG. 13 illustrates another example of the D-D′ cross section of the semiconductor device 100 illustrated in FIG. 11 in the gate finger region 103. In the example of FIG. 13, the width and depth of the gate potential trench GT are different from those of the example of FIG. 11. That is, as compared with the example of FIG. 13, the width of the gate potential trench GT is large, and the bottom position is deep. It can be said that the gate potential trench GT has a larger width and a deeper bottom position than the emitter potential trench ET. For example, when a trench is formed by widening the trench opening width, the bottom position of the formed trench becomes deep. By using this phenomenon, the width of only the gate potential trench GT is widened to form the trench, thus digging the gate potential trench GT deep. As a result, the area of the gate potential trench GT in contact with the N-drift layer ND increases, thus making it possible to further increase the feedback capacitance Cres.

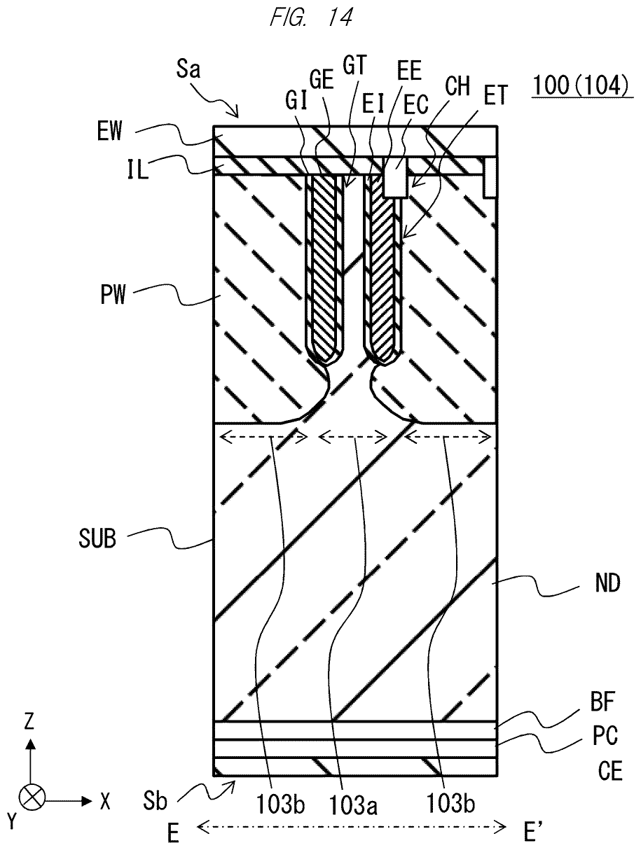

FIG. 14 illustrates an example of an E-E′ cross section of the semiconductor device 100 in FIGS. 7 and 8 in the end region 104 (for example, the end region 104-2) of the active cell region 101. The example of FIG. 14 is an example in which the emitter potential trench-gate potential trench-emitter potential trench structure in FIG. 11 is applied to the gate potential trench-emitter potential trench structure.

As illustrated in FIG. 14, also at the right end of the active cell region 101, the emitter potential trench ET is added along the gate potential trench GT. Thus, the emitter potential trench ET is disposed so as to go around an outer periphery of the active cell region 101. In the example of FIG. 14, the emitter potential trench ET is formed to face the gate potential trench GT as in the GE-type IGBT in FIG. 9. As in FIG. 11, the N-drift layer ND is formed in the region 103a between the gate potential trench GT and the emitter potential trench ET. As in FIG. 11, the P-well region PW is formed in the regions 103b on both sides of the region 103a. The region 103b includes the region on the side of the gate potential trench GT opposite to the side where the emitter potential trench ET is located and the region on the side of the emitter potential trench ET opposite to the side where the gate potential trench GT is located.

As illustrated in FIG. 14, by adding the emitter potential trench so as to run in parallel with the gate potential trench also on the outermost periphery of the active cell region, it is possible to separate the P-well region connected to the emitter potential from the gate potential trench, and to add a region for forming the feedback capacitance Cres.

As described above, the present embodiment provides the semiconductor device having a structure in which the emitter potential trench is disposed so as to surround the gate potential trench in the gate finger region, and the P-well region connected to the emitter potential and the gate potential trench are separated from each other by the emitter potential trench (DCBGT: Damping Capacitance Bare Gate Trench). That is, the emitter potential trench is added to prevent the gate potential trench outside the active cell region from being in contact with the P-well region and to separate the gate potential trench from the P-well region. With this structure, since the gate potential trench is not in contact with the P-well region connected to the emitter potential, the capacitance around the gate potential trench contributes to the feedback capacitance Cres. By increasing the feedback capacitance Cres, it is possible to suppress oscillation at the time of load short circuit. In addition, due to only the layout change outside the active cell region, the DC characteristics of the IGBT are not affected.

Patent Document 1 provides a semiconductor device having a DCT (Damping Capacitance Trench) structure in which the feedback capacitance Cres is added by adding the quadrangular gate potential trench in plan view in the gate finger region, and removing the P-well region inside the quadrangle of the gate potential trench. In Patent Document 1, however, since one side of the added gate potential trench is in contact with the P-well region, there may be influence of gate potential fluctuation (displacement current) at the time of switching. In addition, it is difficult to discharge carriers since there are no emitter potentials around the gate potential trench.

On the other hand, in the present embodiment, since there are no portions where the P-well region connected to the emitter potential is in contact with the gate potential trench, the influence of the gate potential fluctuation (displacement current) at the time of switching can be suppressed. In addition, since the added emitter potential trench acts as a parasitic PMOS (well region, N-drift layer, and P collector layer), discharge of carriers accumulated between the gate potential trench and the emitter potential trench is promoted.

### Second Embodiment

Next, a second embodiment will be described. In the present embodiment, an example will be described in which another semiconductor region is added between the gate potential trench and the emitter potential trench of the semiconductor device described in the first embodiment.

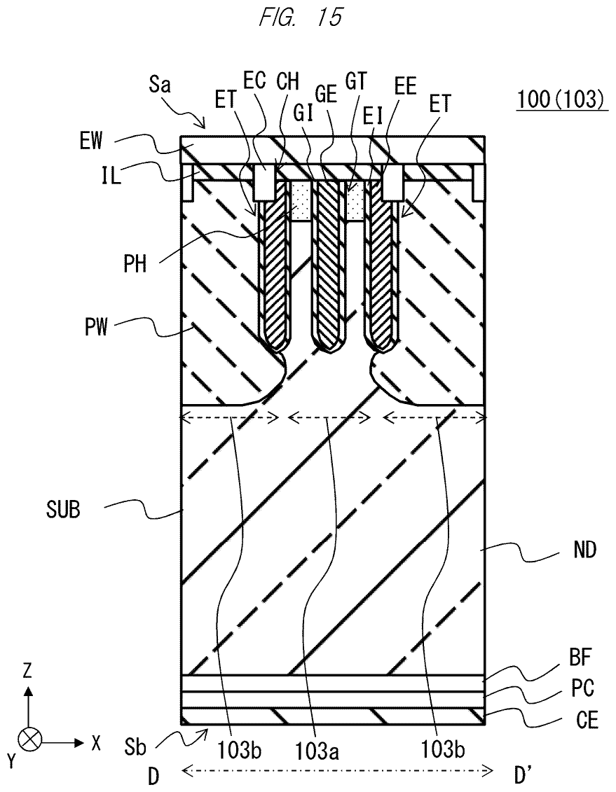

FIG. 15 is an example of a cross-sectional view of the gate finger region 103 of the semiconductor device 100 according to the present embodiment. FIG. 15 is a modification of FIG. 11, and, similarly to FIG. 11, is the D-D′ cross-sectional view of the gate finger region 103 in FIG. 10.

In the example of FIG. 15, the P-channel layer PH is added in the region 103a of the example of FIG. 11. That is, in the region 103a, the P-channel layer PH (channel region) that is a P-type semiconductor region is formed on the N-drift layer ND up to the front surface Sa side of the semiconductor substrate SUB. The depth of the P-channel layer PH is shallower than the bottoms of the gate potential trench GT and the emitter potential trench ET. The P-channel layer PH is the same semiconductor region as the P-channel layer PH of the active cell region 101 in FIG. 9. Note that, as in FIG. 15, the P-channel layer PH may also be added in the end region 104 of the active cell region 101 in FIG. 14.

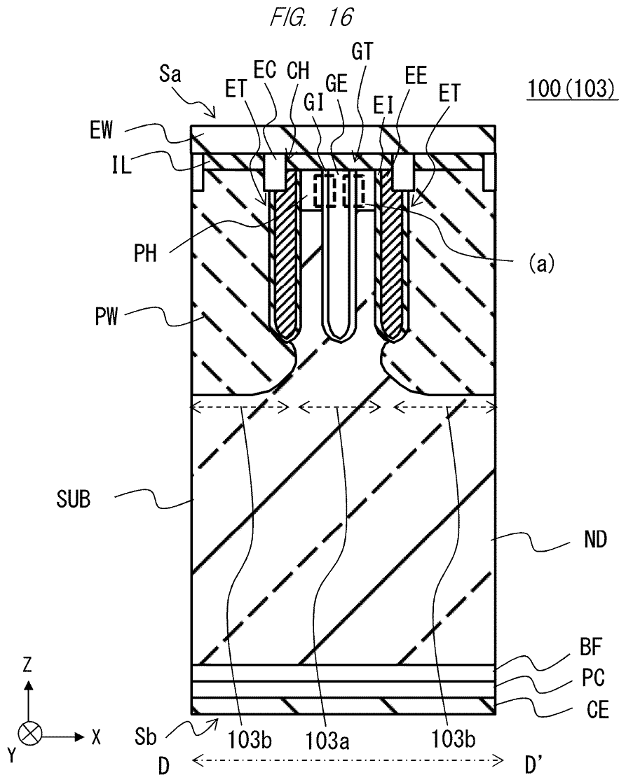

As illustrated in FIG. 16, when the P-channel layer PH is added in the region 103a as illustrated in FIG. 15, the area where the feedback capacitance Cres is formed decreases in the portion (a) of the gate potential trench GT due to the added P-channel layer PH. For example, when the feedback capacitance Cres excessively increases in the configuration of the first embodiment, the P-channel layer PH can be added to adjust the feedback capacitance Cres to be smaller than that in the configuration of the first embodiment.

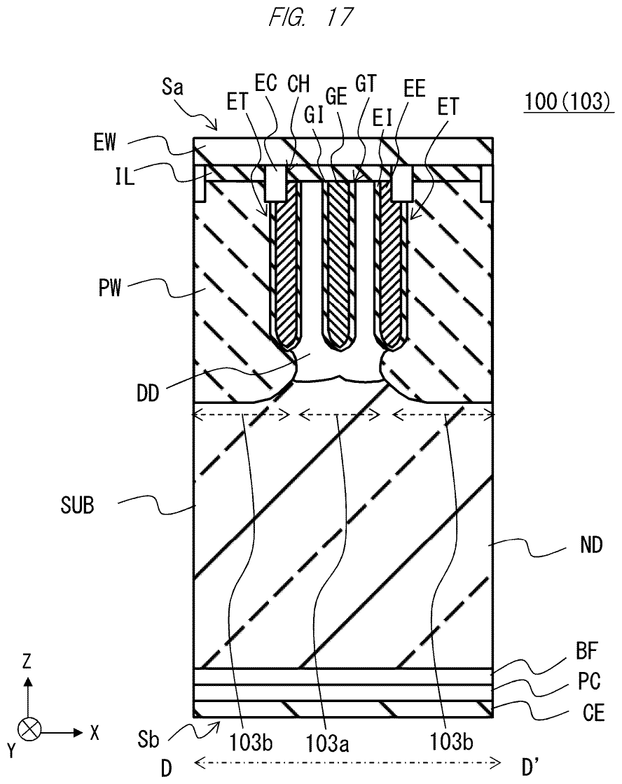

FIG. 17 is another example of the cross-sectional view of the gate finger region 103 of the semiconductor device 100 according to the present embodiment. Similarly to FIG. 15, FIG. 17 is a modification of FIG. 11, and is the D-D′ cross-sectional view of the gate finger region 103 in FIG. 10.

In the example of FIG. 17, the N-hole barrier layer DD is added in the region 103a of the example of FIG. 11. That is, in the region 103a, the N-hole barrier layer DD (hole barrier region) that is an N-type semiconductor region is formed on the N-drift layer ND up to the front surface Sa side of the semiconductor substrate SUB. The depth of the N-hole barrier layer DD is deeper than the bottoms of the gate potential trench GT and the emitter potential trench ET, but is shallower than the P-well region PW. The N-hole barrier layer DD is the same semiconductor region as the N-hole barrier layer DD of the active cell region 101 in FIG. 9. Note that, as in FIG. 17, the N-hole barrier layer DD may also be added in the end region 104 of the active cell region 101 in FIG. 14.

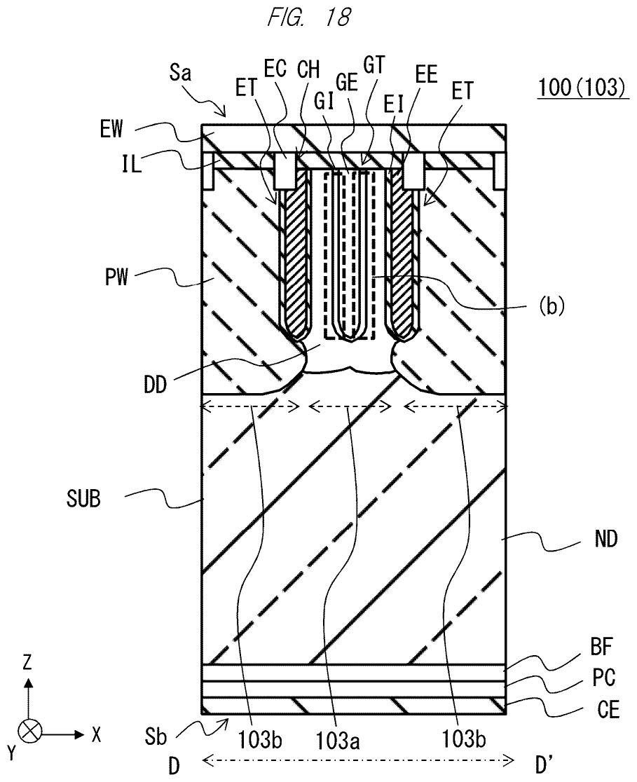

As illustrated in FIG. 18, when the N-hole barrier layer DD is added in the region 103a as illustrated in FIG. 17, carriers contributing to the feedback capacitance Cres increase in the portion (b) (oxide film) of the gate potential trench GT due to the added N-hole barrier layer DD. Therefore, the N-hole barrier layer DD can be added to further increase the feedback capacitance Cres as compared with the configuration of the first embodiment.

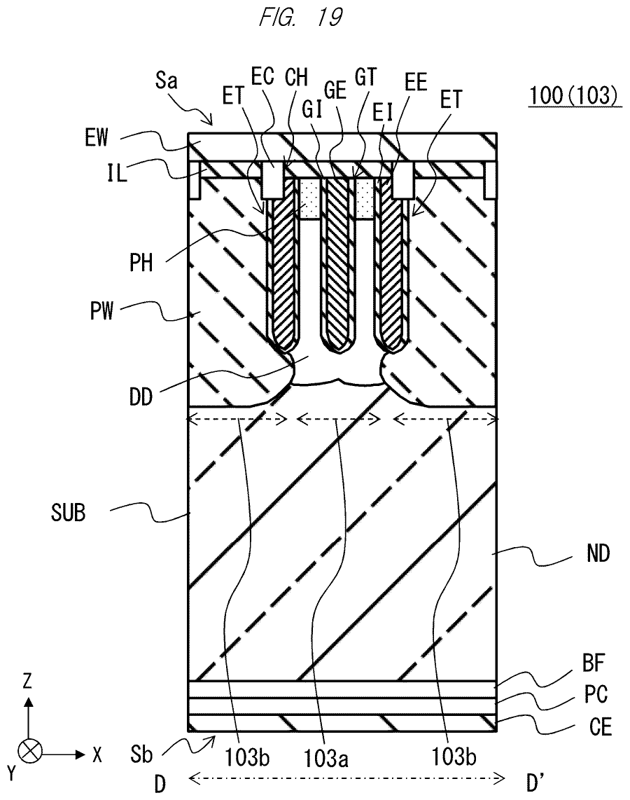

FIG. 19 is still another example of the cross-sectional view of the gate finger region 103 of the semiconductor device 100 according to the present embodiment. Similarly to FIGS. 15 and 17, FIG. 19 is a modification of FIG. 11, and is the D-D′ cross-sectional view of the gate finger region 103 in FIG. 10.

The example of FIG. 19 is an example combining FIGS. 15 and 17. That is, in the example of FIG. 19, the P-channel layer PH and the N-hole barrier layer DD are added in the region 103a of the example of FIG. 11. In the region 103a, the same N-hole barrier layer DD as that in FIG. 17 is formed on the N-drift layer ND, and further, the same P-channel layer PH as that in FIG. 15 is formed on the N-hole barrier layer DD up to the front surface Sa side of the semiconductor substrate SUB. Note that, as in FIG. 19, the P-channel layer PH and the N-hole barrier layer DD may also be added in the end region 104 of the active cell region 101 in FIG. 14.

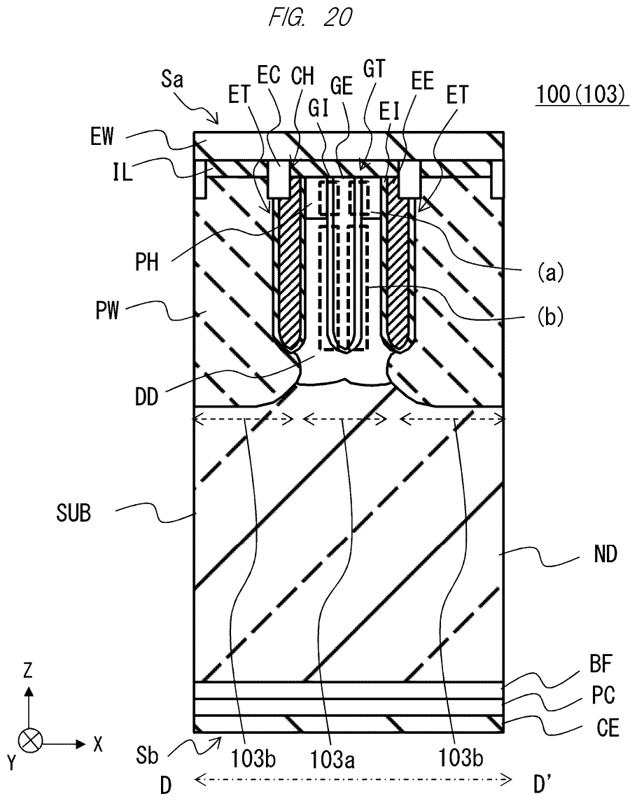

As illustrated in FIG. 20, when the P-channel layer PH and the N-hole barrier layer DD are added in the region 103a as illustrated in FIG. 19, the area where the feedback capacitance Cres is formed decreases in the portion (a) of the gate potential trench GT according to the area of the added P-channel layer PH, and carriers contributing to the feedback capacitance Cres increase in the portion (b) (oxide film) of the gate potential trench GT according to the area of the added N-hole barrier layer DD. Therefore, it is possible to adjust the increase or decrease of the feedback capacitance Cres according to the added amount of the P-channel layer PH and the added amount of the N-hole barrier layer DD.

Note that the input capacitance Cies that is a special capacitance is formed between the gate potential trench GT and the emitter potential trench ET, and this capacitance contributes to stability of the switching characteristics. For example, by adding the N-hole barrier layer DD as illustrated in FIG. 19, not only the feedback capacitance Cres but also the input capacitance Cies can be increased. Therefore, the added amount of the N-hole barrier layer DD can be used as a design parameter for adjusting the feedback capacitance Cres and the input capacitance Cies, thus making it possible to secure a degree of freedom in design.

As described above, in the semiconductor device described in the first embodiment, the P-channel layer PH and the N-hole barrier layer DD may be added between the gate potential trench and the emitter potential trench. As a result, the feedback capacitance Cres to be formed can be adjusted, and the input capacitance Cies can also be adjusted. For example, the oscillation at the time of load short circuit can be further suppressed by increasing the feedback capacitance Cres according to the addition of the P-channel layer PH. The switching characteristics can be set more appropriately by adjusting the feedback capacitance Cres and the input capacitance Cies according to the addition of the N-hole barrier layer DD.

Although the invention made by the present inventor has been specifically described based on the embodiments, it will be appreciated that the present invention is not limited to the above-described embodiments and various modifications can be made without departing from the gist of the present invention.

For example, in the semiconductor device according to the above embodiment, the conductivity type (P-type or N-type) of the semiconductor substrate, the semiconductor layer, the diffusion layer (diffusion region), or the like may be inverted. Therefore, when one of the N-type and P-type conductivity types is used as the first conductivity type and the other conductivity type is used as the second conductivity type, the first conductivity type can be the P-type and the second conductivity type can be the N-type, and conversely, the first conductivity type can be the N-type and the second conductivity type can be the P-type.

What is claimed is:

1. A semiconductor device comprising:
a semiconductor substrate including an active cell region where a transistor is formed so as to be operable and a gate finger region where a gate wiring is led out,
wherein a gate potential trench formed on a main surface side of the semiconductor substrate,
predetermined potential trenches formed on the main surface side of the semiconductor substrate so as to sandwich the gate potential trench and having a predetermined potential different from a gate potential,
a drift region of a first conductivity type formed in a first region between the gate potential trench and the predetermined potential trench in the semiconductor substrate, and
a well region of a second conductivity type, which is a region above the drift region in the semiconductor substrate and formed in a second region on a side of the predetermined potential trench opposite to a side where the gate potential trench is located
are provided in the gate finger region.

2. The semiconductor device according to claim 1,
wherein the well region is connected to the predetermined potential, and
wherein the gate potential trench and the well region are separated from each other.

3. The semiconductor device according to claim 1,
wherein the gate potential trench is covered with the drift region from the main surface side of the semiconductor substrate to a bottom of the gate potential trench.

4. The semiconductor device according to claim 1,
wherein a width of the gate potential trench is wider than a width of the predetermined potential trench.

5. The semiconductor device according to claim 1,
wherein a depth of the gate potential trench is deeper than a depth of the predetermined potential trench.

6. The semiconductor device according to claim 1,
wherein a channel region of the second conductivity type formed above the drift region is provided in the first region.

7. The semiconductor device according to claim 1,
wherein a hole barrier region of the first conductivity type formed above the drift region is provided in the first region.

8. The semiconductor device according to claim 7,
wherein a channel region of the second conductivity type formed above the hole barrier region is provided in the first region.

9. The semiconductor device according to claim 1, further comprising:
at an end portion of the active cell region extending in a direction orthogonal to a direction in which the gate finger region extends in plan view,
the gate potential trench;
the predetermined potential trench formed so as to face the gate potential trench; and
the drift region formed in a region between the gate potential trench and the predetermined potential trench at the end portion.

10. The semiconductor device according to claim 1,
wherein the gate finger region is a region that is outside the active cell region in plan view and extends along a first end portion of the active cell region.

11. The semiconductor device according to claim 1,
wherein a plurality of the active cell regions are provided, and
wherein the gate finger region is a region between the plurality of active cell regions.

12. The semiconductor device according to claim 1, further comprising:
an interlayer insulating film formed on the semiconductor substrate;
a predetermined potential wiring formed on the interlayer insulating film; and
a predetermined potential contact that connects the predetermined potential wiring to the predetermined potential trench and the well region via the interlayer insulating film.

13. The semiconductor device according to claim 1, further comprising:
an interlayer insulating film formed on the semiconductor substrate;
a gate wiring formed on the interlayer insulating film; and
a gate contact that connects the gate wiring to the gate potential trench via the interlayer insulating film.

14. The semiconductor device according to claim 1,
wherein the transistor is an insulated gate bipolar transistor (IGBT).

15. The semiconductor device according to claim 14,
wherein the predetermined potential trench is an emitter potential trench connected to an emitter potential.

16. A semiconductor device comprising:
a semiconductor substrate including an active cell region where a transistor is formed so as to be operable,
wherein a gate potential trench formed on a main surface side of the semiconductor substrate,
a predetermined potential trench formed on the main surface side of the semiconductor substrate so as to face the gate potential trench and having a predetermined potential different from a gate potential,
a drift region of a first conductivity type formed in a first region between the gate potential trench and the predetermined potential trench in the semiconductor substrate, and
a well region of a second conductivity type, which is a region above the drift region in the semiconductor substrate and formed in a second region on a side of the predetermined potential trench opposite to a side where the gate potential trench is located
are provided at an end portion of the active cell region.
